(19) United States
(12) Patent Application Publication
(10) Pub. No.: US 2026/0099651 A1
(43) Pub. Date: Apr. 9, 2026

(54) MULTI-AGENT TRAJECTORY PREDICTION SYSTEM AND METHOD OF OPERATING THE SAME

(71) Applicant: HON HAI PRECISION INDUSTRY CO., LTD., New Taipei City (TW)

(72) Inventors: Yung-Hui LI, New Taipei City (TW); Shen-Hsuan LIU, New Taipei City (TW); Yi-Rong LIN, New Taipei City (TW); Kai-Lin YANG, New Taipei City (TW); Zikang ZHOU, New Taipei City (TW); Jianping WANG, New Taipei City (TW)

(21) Appl. No.: 19/333,376

(22) Filed: Sep. 19, 2025

Related U.S. Application Data
(60) Provisional application No. 63/704,572, filed on Oct. 8, 2024.

(51) Int. Cl. G06F 30/27

(52) U.S. Cl. CPC G06F 30/27

(57) ABSTRACT

A method of operating a multi-Agent trajectory prediction system, comprising: filtering a plurality of agents to generate a plurality of target agents; encoding a plurality of first agent data of the plurality of target agents to generate a scene data; generating a first computation result and a second computation result according to the scene data; performing a row-wise computation to each of the first computation result and the second computation result to generate a first prediction result; performing a column-wise computation to the first prediction result to generate a second prediction result; and generating a plurality of prediction results of the plurality of target agents according to the second prediction result.

### RELATED APPLICATIONS

This application claims priority to U.S. Provisional Application Ser. No. 63/704,572, filed Oct. 8, 2024, which is herein incorporated by reference.

### BACKGROUND

### Technical Field

The present disclosure relates to a multi-agent trajectory prediction system and method of operating the same. More particularly, the present disclosure relates to a multi-agent trajectory prediction system for traffic scenes and the operating method thereof.

### Description of Related Art

In the existing system and method for predicting trajectories, it is practical to generate several possible trajectories of multiple driving paths for trajectory prediction of vehicles. However, these trajectories are potential trajectories predicted merely based on the driving status of an individual vehicle that interacted with surroundings, which is unreliable to effectively take the interactions among different vehicles into consideration. In addition, the predicted trajectories of each vehicle are independent in a multi-vehicle scene.

In other words, the existing trajectory predicting system does not consider a joint interaction between multiple trajectories generated for different vehicles. As a result, when the predicted trajectories of different vehicles are cross intersected or overlapped, it remains a further improvement of the prediction system for considering whether the practical trajectories that the vehicles drive through are fully taken into account and providing effective warnings.

### SUMMARY

The present disclosure provides a method of operating a multi-Agent trajectory prediction system. The method comprises filtering a plurality of agents and generating a plurality of target agents; encoding a plurality of first agent data of the plurality of target agents to generate a scene data; generating a first computation result and a second computation result according to the scene data; performing a row-wise computation to each of the first computation result and the second computation result to generate a first prediction result; performing a column-wise computation to the first prediction result to generate a second prediction result; and generating a plurality of prediction results of the plurality of target agents according to the second prediction result.

The present disclosure provides a multi-Agent trajectory prediction system. The multi-Agent trajectory prediction system comprises: a filter configured to filter a plurality of agents and generate a plurality of target agents; an encoder configured to encode a plurality of agent data of the plurality of target agents to generate a scene data; and a decoder configured to perform the following operations: generating a first computation result and a second computation result according to the scene data; performing a row-wise computation to the first computation result and the second computation result, and generating a first prediction result; and performing a column-wise computation to the first prediction result, and generating a second prediction result, wherein the second prediction result is configured to describe a plurality of trajectories of the plurality of target agents.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a multi-agent trajectory prediction system, illustrated in accordance with some embodiments of the present disclosure.

FIG. 2 is a schematic diagram of a device for implementing a multi-agent trajectory prediction system, illustrated in accordance with some embodiments of the present disclosure.

FIG. 3 is a flowchart diagram of an operating process of a multi-agent trajectory prediction system, illustrated in accordance with some embodiments of the present disclosure.

FIG. 4 is a flowchart diagram of an operating process of a multi-agent trajectory prediction system, illustrated in accordance with some embodiments of the present disclosure.

FIG. 5 is a flowchart diagram of a method for operating a multi-agent trajectory prediction system, illustrated in accordance with some embodiments of the present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

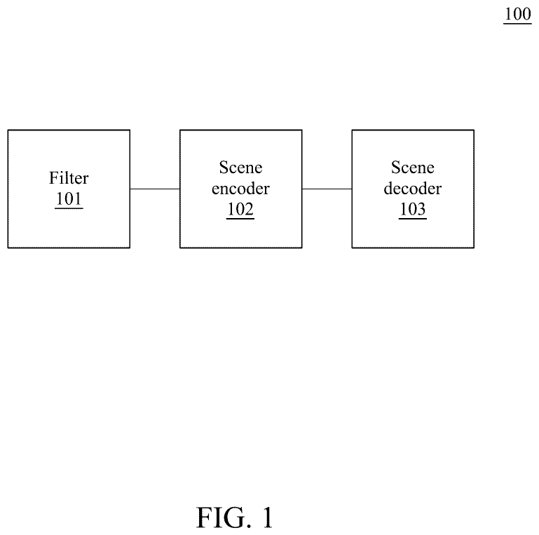

FIG. 1 is schematic diagram of a multi-agent trajectory prediction system 100, illustrated in accordance with some embodiment of the present disclosure. As illustratively shown in FIG. 1, the multi-agent trajectory prediction system 100 includes a filter 101, a scene encoder 102, and a scene decoder 103.

In some embodiments, the filter 101 is connected to the scene encoder 102. The scene encoder 102 is connected to the scene decoder 103.

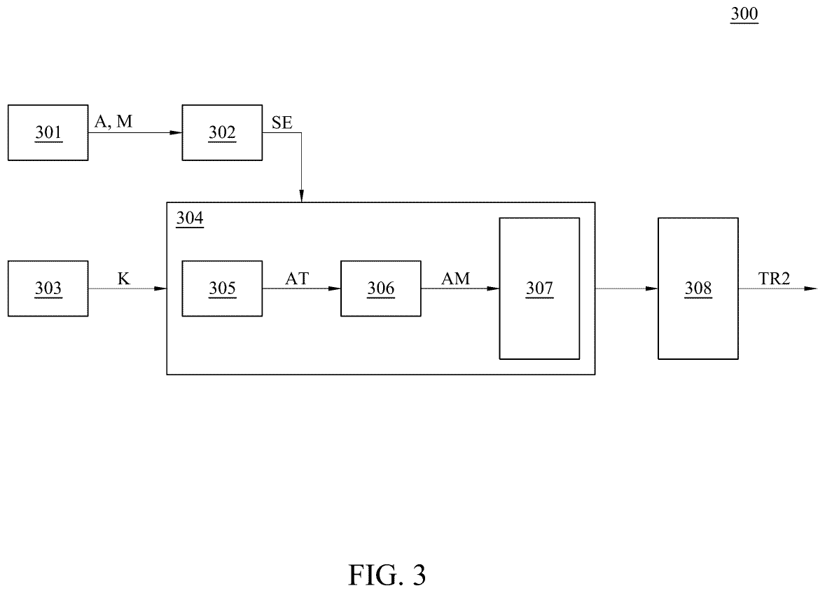

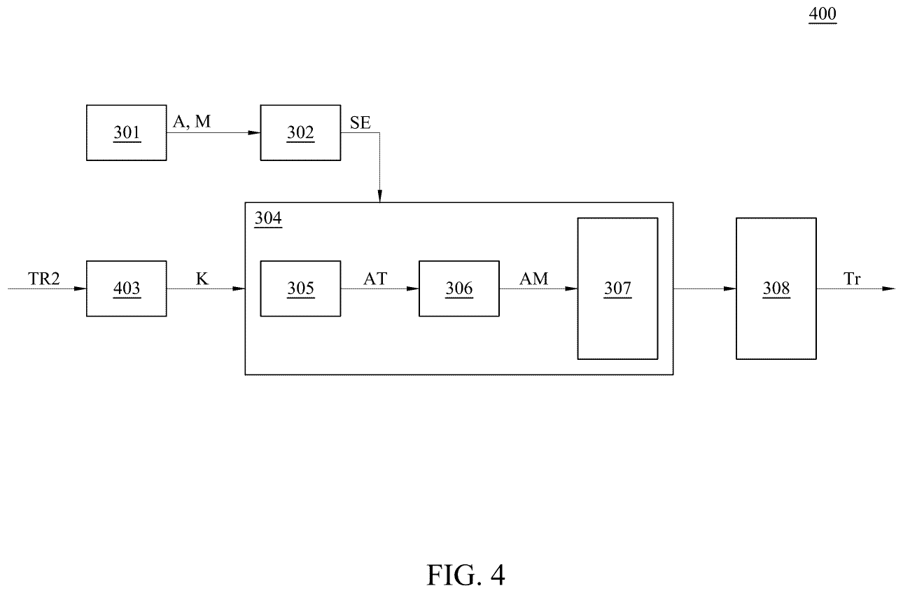

In some embodiments, the filter 101 is configured to filter out multiple target agents A from multiple agents AG, and transmit an agent data AD of the target agents A and a map data M to the scene encoder 102. The scene encoder 102 is configured to encode the agent data AD of the target agents A and the map data MD to generate an encoded scene data SE, and transmit the scene data SE to the scene decoder 103 for decoding and calculating. The scene decoder 103 performs a computation of attention algorithm to the scene data SE, and performs a Row-Wise computation and a Column-Wise computation to generate a trajectory prediction result. Further details regarding the data training and the computing process of the multi-agent trajectory prediction system 100 are discussed in FIG. 3 and FIG. 4 and the corresponding paragraphs of the present disclosure.

In some embodiments, the multi-agent trajectory prediction system 100 can be applied to an automotive vehicle AS itself, and other vehicles, cars, or any traffic systems having a sensor and a processor. In some embodiments, the agents AG includes multiple vehicles, cars, pedestrians or other similar objects other than the automotive vehicle AS, but the present disclosure is not limited this.

In some embodiments, the agents AG include agent data AG_D and map data AG_M. In some embodiments, the agent data AG_D includes the motional statuses and the positions of the agents AG at different time T, but the present disclosure is not limited to these data. In some embodiments, the map data AG_M includes the map data of scenes SC where the agents AG are located, but the present disclosure is not limited to this.

In some embodiments, the target agents A are part of the agents that are filtered out from the agents AG. Correspondingly, the agent data AD of the target agents A includes the motional statuses and the positions of the target agents A at different time T. The map data M of the target agents A includes the map data of the scenes SC where the target agents A are located.

In some approaches, the trajectory prediction to cars or vehicles is the predicted trajectory generated according to the driving status of individual vehicle and conditions of the surrounding. However, when there are multiple vehicles, each of the predicted trajectories corresponding to the vehicles is independent. The trajectory prediction system in these approaches does not jointly consider the interaction of multiple predicted trajectories generated for different vehicles. Therefore, when the predicted trajectories of different vehicles are cross intersected or overlapped, the trajectory prediction system is unable to provide a comprehensive vehicle status and trajectory prediction.

In some embodiments of the present disclosure, when the multi-agent trajectory prediction system 100 performs the trajectory prediction of multiple agents A, the prediction takes the motional statuses and positions of the agents A in to consideration by performing a row-wise arithmetic calculation. In addition, the multi-agent trajectory prediction system 100 further performs a cross-interaction calculation to multiple trajectories predicted from the row-wise arithmetic calculation by performing a column-wise arithmetic calculation to avoid cross intersected or overlapped of the corresponding predicted trajectories of multiple agents A, effectively achieving a more accurate trajectory prediction.

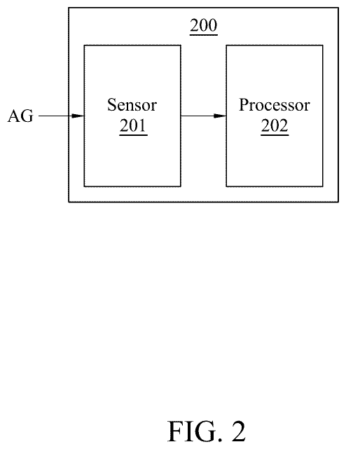

FIG. 2 is a schematic diagram of a device 200 for implementing the multi-agent trajectory prediction system 100, illustrated in accordance with some embodiments of the present disclosure. As illustratively shown in FIG. 2, the device 200 includes a sensor 201 and a processor 202. In some embodiments, the multi-agent trajectory prediction system 100 can be applied to the device 200, and implemented by the sensor 201 and the processor 202.

In some embodiments, the sensor 201 is configured to perform a scanning to a visible range to identify multiple agents AG, and generate the agent data AG_D and the map data AG_M corresponding to the agents AG. The processor 202 is configured to perform the data training and calculation to the agents AG in the multi-agent trajectory prediction system 100 and generate a predicted trajectory Tr.

In some embodiments, the processor 202 can include a central processing unit (CPU), a multiprocessor, a distributed processing system, an application specific integrated circuit (ASIC), or other similar computational units, but the present disclosure is not limited to these units.

In some embodiments, the sensor 201 is configured to connect external devices to detect and scan multiple agents AG. In some embodiments, the external devices can be the camera of a vehicle, a radar transceiver, a light detection and ranging (LiDAR) transceiver, or other devices that are able to retrieve the position and motional status of an agent in a scene, but the present disclosure is not limited to these devices.

FIG. 3 is a flowchart diagram of an operating process 300 of the multi-agent trajectory prediction system 100, illustrated in accordance with some embodiments of the present disclosure. As illustratively shown in FIG. 3, the operating process 300 includes blocks 301-308. In some embodiments, the operating process 300 is configured to perform a computation of Anchor-Free mode attention algorithm.

Referring to FIG. 3 and FIG. 1, the block 301 corresponds to the operating process of the filter 101. The block 302 corresponds to the operating process of the scene encoder 102. The block 303-308 corresponds to the operating process of the scene decoder 103.

In the block 301, the filter 101 performs a filtering to multiple agents AG scanned by the sensor 201, and generates the target agents A after filtering.

Specifically, the filter 101 trains the actual agent data of each of the agents AG during a time period TP in the past, and generates a query configurator QC. In some embodiments, the query configurator QC performs a weight computation to the agent data AG_D of the agents AG, and indicates a computation result Q including the correlation between the agents AG and the automotive vehicle AS in forms of an indicator function.

Then, the filter 101 filters out multiple agents in the agents AG having higher correlations to the automotive vehicle AS as the target agents A according to the computation result Q. The filter 101 further transmits the target agents A and the corresponding agent data AD and map data M to the block 302.

For example, in some circumstance, the sensor 201 identifies 50 the agents AG when scanning in a visible range, the filter 101 can perform a computation based on the query configurator QC, and filter out the target agents A having a higher correlation to the automotive vehicle AS according to the computation result Q and a correlation threshold. For example, when the computation result Q has 10 agents AG whose correlations are higher than the correlation threshold, the filter 101 filters out the these 10 agents AG discussed above as the target agents A, but the present disclosure is not limited to this quantity of agents.

In some embodiments, when the correlation is higher, physical distances between the agents AG and the automotive vehicle AS are shorter. When the correlation is lower, physical distances between the agents AG and the automotive vehicle AS are longer.

In some embodiments, the time period includes periods between multiple times T in the past, such as a period of 10 seconds in the past. Wherein, each of the times T includes multiple periods, the quantity of these periods corresponds to the number of frame per second (FPS) that the sensor 201 scans. For example, when the number of frame is 240 FPS at time T, the screen that the sensor 201 scans in each second of a period includes 240 frames.

In some embodiments, the number of frame can be adjusted according to the computing power of the processor 202 and the resolution that the sensor 201 can process, but the present disclosure is not limited to 240 FPS discussed above.

In some embodiments, the quantity of the target agents A can be adjusted according to the computing power of the processor 202 to match the computational capacity. For example, when the computing power of the processor is higher, the quantity of the target agents A is higher. When the computing power of the processor is lower, the quantity of the target agents A is lower.

In the block 302, the scene encoder 102 performs an encoding according to the agent data AD of the target agents A at different times T and the map data M to generate the scene data SE, and the scene data SE has a tensor [A, T, M].

Specifically, the scene encoder 102 encodes the target agents A into the row vectors of the scene data SE matrix, and encodes multiple times T in the time period into the column vectors of the scene data SE matrix. In addition, the scene encoder 102 encodes the scenes SC in the map data M into the scene data SE in order according to the times T. Therefore, each of the vector elements in the scene data SE indicates the agent data AD of the target agents A in the scenes SC at times T, and the scene data SE can be interpreted as follow.

$$SE = {\sum }_{ij} {A ( T )}_{ij} {M}_{i}$$

Wherein, i and j are integers. Then, the scene encoder 102 further transmits the scene data SE to the block 304 to perform the computation of attention algorithm.

In some embodiments, the agent data AD is configured to indicate the positions and motional statuses of the target agents A at each of the corresponding times T in the past period of time. For example, the agent data AD can include the state information such as position, velocity, and direction of the target agents A at each of the times T.

In the block 303, the scene decoder 103 performs an anchor-free mode parametric initialization to the computation of attention algorithm, and is configured to generate multiple queries K according to the target agents A and a quantity N of predicted trajectories. The queries K can be interpreted as follow.

$${K}_{j} = {\sum }_{ij} {A}_{ij}$$

Wherein j is an integer.

In some embodiments, the queries K can be one or multiple queries, and the queries K can be interpreted as the initialization vectors of the predicted trajectories. For example, when the quantity N of the predicted trajectories is equal to 7, there are 7 sets of the queries K. Alternatively stated, when performing a prediction with 7 trajectories, the integer j has a value of 7.

In some embodiments, when the computation of attention algorithm with the queries K has performed, the queries K can be interpreted as the trajectories predicted by the multi-agent trajectory prediction system 100.

In the block 304, the scene decoder 103 is configured to perform the computation of attention algorithm according to the scene data SE and the queries K. Wherein, the block 304 includes the blocks 305-307.

In the block 305, the scene decoder 103 performs a computation of time attention algorithm. The computation of time attention algorithm is configured to perform a computation of cross-attention algorithm according to the target agents A in the scene data SE and the time vector of the times T to generate a first computation result AT. Wherein, the first computation result AT has a tensor [A,T].

Specifically, the computation of time attention algorithm can transfer the agent data AD of the target agents A to the query, key, and value in the cross-attention mechanism, and perform the computation of cross-attention algorithm to the time vector of the times T to generate the first computation result AT. In some embodiments, the first computation result AT is configured to describe the positions and the motional statuses of the target agents A at each of the times T. The scene decoder 103 transmits the first computation result AT to the block 306 after the computation of time attention algorithm is performed, and performs the computation of the block 306.

In the block 306, the scene decoder 103 performs a computation of map attention algorithm to the first computation result AT. The computation of map attention algorithm is configured to perform the computation of cross-attention algorithm according to the target agents A in the scene data SE and the scene vector of the map data M to generate a second computation result AM. Wherein the second computation result AM has a tensor [A,T] being the same as the first computation result AT.

Specifically, the map attention algorithm can transfer the first computation result AT of the target agents A to the query, key, and value in the cross-attention algorithm, and perform the computation of cross-attention algorithm to the scene vector of the map data M to generate the second computation result AM. In some embodiments, the second computation result AM is configured to describe the positions and the motional statuses of the target agents A in the scene SC of the map data M. The scene decoder 103 performs the computation of the block 307 after the computation of map attention algorithm is performed.

In the block 307, the scene decoder 103 is configured to perform a computation of Row-Wise self-attention algorithm according to the second computation result AM, and generate a first trajectory prediction result TR1 at a future time T′. Wherein, the first trajectory prediction result TR1 has a tensor [A, K, T′].

Specifically, in a circumstance having multiple target agents A, the computation of Row-Wise self-attention algorithm is configured to communicate each of the predicted trajectories P which relatively correspond to the target agents A, and generate the first trajectory prediction result TR1 after communication. Wherein, the first trajectory prediction result TR1 includes multiple trajectories T_row generated after the communication of the predicted trajectories P of the target agents A. The scene decoder 103 performs the operation of the block 308 after the first trajectory prediction result TR1 is generated.

In some embodiments, the performing of the communication can be interpreted as performing addition, subtraction, inner product, outer product, or other similar computational operation to matrixes or vectors.

In some embodiments, the Row-Wise self-attention algorithm can transform the tensor [A, T] of the second computation result AM to the keys and the values in the self-attention algorithm, and perform the computation to the queries K. Wherein, the computation of Row-Wise self-attention algorithm is configured to row-by-row communicate the keys of the queries K in each row with the target agents A in each column. The queries K can be correspondingly referred to as the trajectories T_row.

For example, when performing the quantity of N sets of trajectory predictions, and there are 5 target agents A, each of N rows of the queries K is row-by-row communicated with each column of the agent data AD of the target agents A to generate the first trajectory prediction result TR1. The first trajectory prediction result TR1 is configured to describe the trajectories T_row generated according to the predicted trajectories of the target agents A in the future time T′. In some embodiments, the N sets of predicted trajectories correspond to N rows of the queries K that are arranged in order row-by-row. The quantity of 5 target agents each of which is arranged in order row-by-row, having 5 columns of agent data AD of the target agents A.

In some embodiments, the queries K indicate the initial values of the predicted trajectories. When the computation of Row-Wise self-attention algorithm is performed to the queries K, the queries K have the predicted values after the computation. At this moment, the queries K are then configured to indicate the trajectories T_row.

In some embodiments, the Row-Wise computation is configured to, in a row vector, take each of elements of the row vector as an input vector and perform the computation of self-attention algorithm. Specifically, the Row-Wise computation is configured to give a weight value to the corresponding column of each of the target agents A in each row of the queries K. The target agents A given the weight value are taken as the input vector, and the computation of self-attention algorithm is performed accordingly to generate the trajectories T_row after computation. Wherein, the trajectories T_row can be interpreted by the queries K after the computation. For example, when the queries K has 3 rows, and each row of the queries K has 5 elements, the queries K can be interpreted as a 3 by 5 spatial matrix that has the agent data AD corresponding to 15 target agents A. At this moment, the Row-Wise computation is configured to take 5 agent data AD in each of the first row to the third row of the queries K as the first input vector to the third input vector, respectively, and the computation of self-attention algorithm is performed with the first input vector to the third input vector, and generates the trajectories T_row having a 3 by 5 spatial matrix.

In the block 308, the scene decoder 103 performs a computation of Column-Wise self-attention algorithm to the first trajectory prediction result TR1, and generates a second trajectory prediction result TR2 at the future time T′. Wherein, the second trajectory prediction result TR2 has a tensor [A,K′,T′].

In some embodiments, the computation of Column-Wise self-attention algorithm is configured to perform a column-by-column interactive computation to each row of the queries K. Alternatively stated, the computation of Column-Wise self-attention algorithm is configured to communicate each of the trajectories T_row, and generates the second trajectory prediction result TR2.

Specifically, the computation of Column-Wise self-attention algorithm communicates the rows of the queries K with each other, and generates the second trajectory prediction result TR2 after communication. The second trajectory prediction result TR2 includes multiple predicted trajectories T_col generated after the communication between each rows of the queries K.

Alternatively stated, the queries K′ are generated after the Computation of Column-Wise self-attention algorithm is performed to the queries K.

For example, when the first trajectory prediction result TR1 has a quantity of N trajectories T_row, each rows of the queries K corresponding to N trajectories T_row is column-by-column communicated with each row of queries K to generate the second trajectory prediction result TR2. The second trajectory prediction result TR2 is configured to describe multiple predicted trajectories T_col generated from the interaction of multiple trajectories T_row in the future time T′. At this moment, the queries K′ can be referred to as the trajectories T_col.

In some embodiments, the Column-Wise computation is configured to, in multiple row vectors, take each column elements of the row vectors as the input vector and perform the computation of self-attention algorithm. Specifically, the Row-Wise computation is configured to give a weight value to elements in each row of the trajectories T_row, take column elements in each row of the trajectories T_row as the input vector, and perform the computation of self-attention algorithm to generate the trajectories T_col after the computation. Wherein, the trajectories T_col can be interpreted by the queries K′ after the computation. For example, when the trajectories T_row has 3 rows, and each row of the trajectories T_row has 5 elements, the trajectories T_row can be interpreted as a 3 by 5 spatial matrix, having 15 elements. At this moment, the Column-Wise computation is configured to take the elements of the first column to the fifth column as the first input vector to the fifth input vector, respectively, and the computation of self-attention algorithm is performed with the first input vector to the fifth input vector, and generates the trajectories T_col having a 3 by 5 spatial matrix. In some circumstances, the first trajectory prediction result TR1 generated by the scene decoder 103 in the computation of the block 307 can describe the predicted trajectories T_row generated from the predicted trajectories P of the target agents A at the future time T′. However, the predicted trajectories T_row discussed above may be overlapped or intersected to each other, or other similar impractical conditions.

In some other circumstances, the second trajectory prediction result TR2, generated by the scene decoder 103 after performing the computation of the block 308, can describe the trajectories T_col that are generated after the interaction of multiple trajectories T_row at the future time T′. The trajectories T_col do not overlapped or intersected to each other, do not have other impractical conditions.

In some embodiments, the second trajectory prediction result TR2 includes multiple predicted trajectories P of each of the target agents A. Wherein, the predicted trajectories P have multiple parameters of the target agents A in the SC, the parameters at least include the horizontal coordination, the vertical coordination, moving directions, and moving velocities. However, the present disclosure is not limited to these parameters mentioned above.

In some embodiments, after completing the operating processes of the blocks 304-308, the scene decoder 103 can further perform multiple recurrence computation to the second trajectory prediction result TR2, configuring to lower the error rate ERR of the predicted trajectories in each recurrence.

Alternatively stated, the scene decoder 103 can further take the second trajectory prediction result TR2 as the queries K in the block 304, and repeat the operating processes of the blocks 304-308 according to the scene data SE and the second trajectory prediction result TR2 to lower the error rate ERR. In some embodiments, when the repeated times of the recurrence computation is higher, the error rate ERR is lower.

In some embodiments, the error rate ERR describes the errors of the second trajectory prediction result TR2 relative to the historical actual trajectory data in a circumstance having multiple target agents A.

In some embodiments, the error rate ERR can be expressed by a loss function, having the following form.

$$ERR = {\sum }_{k = 1}^{N} {π}_{k} {\prod }_{i = 1}^{A} {\prod }_{t = 1}^{T ′} L ( {p}_{i}^{t , x} \vert {μ}_{i , k}^{t , x} , {b}_{i , k}^{t , x} ) * L ( {p}_{i}^{t , x} \vert {μ}_{i , k}^{t , y} , {b}_{i , k}^{t , y} )$$

In some embodiments,

$$L ( {p}_{i}^{t , x} \vert {μ}_{i , k}^{t , y} , {b}_{i , k}^{t , y} )$$

is configured to describe the historical actual trajectory, and

$$L ( {p}_{i}^{t , x} \vert {μ}_{i , k}^{t , x} , {b}_{i , k}^{t , x} )$$

is configured to describe the second trajectory prediction result TR2. In some embodiments, the summation symbol Σ in the outer-most layer of the loss function is configured to describe the computation of Column-Wise self-attention algorithm, and the product symbol π in the middle layer of the loss function is configured to describe the computation of Row-Wise self-attention algorithm.

FIG. 4 is a flowchart diagram of an operating process 400 of the multi-agent trajectory prediction system 100, illustrated in accordance with some embodiments of the present disclosure. As illustratively shown in FIG. 4, the operating process 400 includes the blocks 301-302 and the blocks 304-308 of the operating process 300 shown in FIG. 3. In some embodiments, the operating process 400 is similar to the operating process 300, thus the similarities are not repeated herein for brevity. In some embodiments, the operating process 400 is configured to perform a computation of Anchor-Based mode attention algorithm.

In some embodiments, the difference between the operating process 400 and the operating process 300 is at the block 403. In the block 403, when the multi-agent trajectory prediction system 100 completes the operating process 300, the generated second trajectory prediction result TR2 can be further input into the block 403 as the initial values of the queries K.

In some embodiments, when the second trajectory prediction result TR2 generated in the operating process 300 is input to the block 403 as the initial values of the queries K, the multi-agent trajectory prediction system 100 repeats the operating processes of the blocks 301-302 and the blocks 304-308, and generates multiple fine-tuned predicted trajectories Tr. Wherein, the predicted trajectories Tr has a tensor [A,K′,T′].

In some embodiments, each of the predicted trajectories Tr includes the predicted trajectories P′ of each of the target agents A. Wherein, the predicted trajectories P′ indicates the fine-tuned predicted trajectories generated from the predicted trajectories P in the second trajectory prediction result TR2 through the operating process 400.

In some embodiments, the predicted trajectories P′ have multiple parameters of the target agents A in the scene SC, the parameters at least include the horizontal coordination, the vertical coordination, moving directions, and moving velocities. However, the present disclosure is not limited to these parameters mentioned above.

In some embodiments, the multi-agent trajectory prediction system 100 is able to control the automotive vehicle AS according to the predicted trajectories Tr. When the trajectory that the automotive vehicle AS went through is overlapped with the predicted trajectories Tr, the multi-agent trajectory prediction system 100 controls the automotive vehicle AS to turn and/or stop to prevent the automotive vehicle AS from passing through the predicted trajectories Tr.

In some circumstances, when the multi-agent trajectory prediction system 100 performs the anchor-free mode parametric initialization such as the operating process 300, the quantity of the queries K is not limited to a specific range.

For example, when the anchor-based mode parametric initialization is performed, the predicted trajectories (the queries K) are not limited to some regulated directions, such as straight, 45 degrees shift to the right, 45 degrees shift to the left, or other similar regulated directions, but the present disclosure is not limited to this.

In some other circumstances, when the multi-agent trajectory prediction system 100 performs the anchor-based mode parametric initialization such as the operating process 400, the quantity of the queries K can be limited to a specific range.

For example, the queries K correspond to the predicted trajectories. When the anchor-based mode parametric initialization is performed, the predicted trajectories can be limited to specific regulated directions, such as straight, 45 degrees shift to the right, 45 degrees shift to the left, or other similar regulated directions, but the present disclosure is not limited to this.

In some embodiments, the multi-agent trajectory prediction system 100 performs the anchor-free mode parametric computation to generate the predicted trajectories Tr corresponding to the second trajectory prediction result TR2. When the multi-agent trajectory prediction system 100 generates the predicted trajectories Tr, the multi-agent trajectory prediction system 100 performs the anchor-based mode parametric computation to fine-tune the second trajectory prediction result TR2, and generates the fine-tuned predicted trajectories Tr, to lower the dimension of the computation and enhance the accuracy of the trajectory prediction. Based on above, when the anchor-free mode parametric computation is performed, the multi-agent trajectory prediction system 100 generates a quantity of N1 predicted trajectories Tr. When the anchor-based mode parametric computation is performed, the multi-agent trajectory prediction system 100 calculates a quantity of N2 fine-tuned predicted trajectories Tr based on the quantity of N1 predicted trajectories Tr. Wherein, N1 and N2 are integers, and the integer N1 is equal to the integer N2.

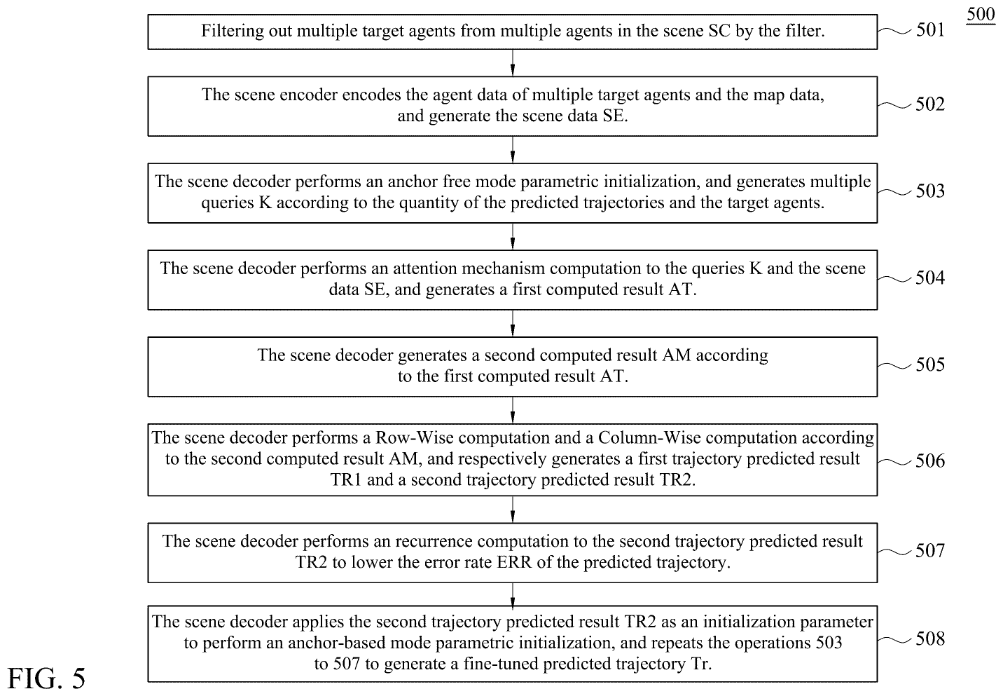

FIG. 5 is a flowchart diagram of a method 500 for operating a multi-agent trajectory prediction system, illustrated in accordance with some embodiments of the present disclosure. As illustratively shown in FIG. 5, the method 500 includes operations 501-508.

Referring to FIG. 5, FIG. 4, and FIG. 3, the operation 501 corresponds to the block 301 of the operating process 300. The operation 502 corresponds to the block 302 of the operating process 300. The operation 503 corresponds to the block 303 of the operating process 300. The operations 504 and 505 correspond to the blocks 305 and 306 of the operating process 300. The operation 506 corresponds to the blocks 307 and 308 of the operating process 300. The operation 507 corresponds to the blocks 304-308 of the operating process 300. The operation 508 corresponds to the block 403 of the operating process 400.

In the operation 501, the filter 101 filters out multiple target agents A from the agents AG in the scene SC.

Specifically, the filter 101 performs a filtering to multiple agents AG based on the scanning in a visible range by the sensor 201 shown in FIG. 2, and filters out multiple the target agents A. The multi-agent trajectory prediction system 100 performs the operation 502 after the operation 501 is performed.

In the operation 502, the scene encoder 102 encodes the agent data AD of the target agents A and the map data M, and generates the scene data SE.

In some embodiments, the scene data SE is configured to describe the agent data AD of the target agents A in the scene SC at each time T in the past period of time. The multi-agent trajectory prediction system 100 performs the operation 503 after the operation 502 is performed.

In the operation 503, the scene decoder 103 performs the anchor-free mode parametric initialization, and generates multiple queries K according to the quantity N of the target agents A and the predicted trajectories.

In some embodiments, the queries K is a vector describing the predicted trajectories, and the quantity of the queries K is equal to the quantity N of the predicted trajectories. The multi-agent trajectory prediction system 100 performs the operation 504 after the operation 503 is performed.

In the operation 504, the scene decoder 103 performs the computation of attention algorithm to the queries K and the scene data SE, and generates the first computation result AT. The multi-agent trajectory prediction system 100 performs the operation 505 after the operation 504 is performed.

In some embodiments, the first computation result AT is configured to describe the motional statuses, paths, velocities, directions or other similar information of the target agents A at each time T in a time period.

In the operation 505, the scene decoder 103 generates the second computation result AM according to the first computation result AT. Specifically, the scene decoder 103 performs the computation of cross-attention algorithm to the target agents A and the scene vector of the map data M in the first computation result AT to generate the second computation result AM. The multi-agent trajectory prediction system 100 performs the operation 506 after the operation 505 is performed.

In some embodiments, the second computation result AM is configured to describe the map data M of the target agents A in the scene SC at each times T in a time period.

In the operation 506, the scene decoder 103 performs the Row-Wise computation and the Column-Wise computation according to the second computation result AM, and generates the first trajectory prediction result TR1 and the second trajectory prediction result TR2, respectively.

Specifically, the scene decoder 103 performs the Row-Wise computation and generates the first trajectory prediction result TR1 according to the second computation result AM and the predicted trajectories P of each of the target agents A. The scene decoder 103 further performs the Column-Wise computation to the first trajectory prediction result TR1 to generate the second trajectory prediction result TR2. The multi-agent trajectory prediction system 100 performs the operation 507 after the operation 506 is performed.

In the operation 507, the scene decoder 103 performs a recurrence computation to the second trajectory prediction result TR2 to lower the error rate ERR of the predicted trajectories. The multi-agent trajectory prediction system 100 performs the operation 508 after the operation 507 is performed.

In some embodiments, when the error rate ERR is lower, the predicted trajectories are closer to the historical actual trajectories. When the error rate ERR is higher, the predicted trajectories deviate farther to the historical actual trajectories. In some embodiments, when the recursive times of the recurrence computation is higher, the error rate ERR is lower.

In the operation 508, the scene decoder 103 applies the second trajectory prediction result TR2 as an initialization parameter to perform the anchor-based mode parametric initialization, and repeats the operations 503 to 507 to generate the fine-tuned predicted trajectories Tr.

Specifically, the scene decoder 103 takes the queries K′ of the second trajectory prediction result TR2 as the initial value, and performs the anchor-based mode parametric initialization. In addition, the scene decoder 103 takes the target agents A and the map data M of the second trajectory prediction result TR2 as the scene data SE, and repeats the computation of attention algorithm in the operations 503 to 507. The scene decoder 103 generates the fine-tuned predicted trajectories Tr after the computation of anchor-based algorithm is performed. The multi-agent trajectory prediction system 100 completes the method 500 after the operation 508 is performed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating a multi-Agent trajectory prediction system, comprising:
filtering a plurality of agents and generating a plurality of target agents;
encoding a plurality of first agent data of the plurality of target agents to generate a scene data;
generating a first computation result and a second computation result according to the scene data;
performing a row-wise computation to each of the first computation result and the second computation result to generate a first prediction result;
performing a column-wise computation to the first prediction result to generate a second prediction result; and
generating a plurality of prediction results of the plurality of target agents according to the second prediction result.

2. The method of claim 1, wherein filtering the plurality of agents comprises:
training a plurality of second agent data of the plurality of agents during a time period in the past to generate a configurator; and
filtering out the plurality of target agents by the configurator according to a correlation of the plurality of agents.

3. The method of claim 2, wherein when the correlation is higher than a correlation threshold, filtering out corresponding agents of the plurality of agents as the plurality of target agents.

4. The method of claim 2, wherein
when physical distances between the plurality of agents and a vehicle are shorter, the correlation is higher, and
when the physical distances between the plurality of agents and the vehicle are longer, the correlation is lower.

5. The method of claim 1, wherein generating the first computation result comprises:
performing a computation of attention algorithm computation to a time vector of the plurality of target agents correspondingly according to the scene data to generate the first computation result,
wherein the computation of attention algorithm is performed with a cross-attention algorithm.

6. The method of claim 5, wherein generating the second computation result comprises:
performing the computation of attention algorithm to a scene vector of the plurality of target agents correspondingly according to the scene data to generate the second computation result.

7. The method of claim 6, wherein the first computation result has a tensor being the same as a tensor of the second computation result.

8. The method of claim 1, wherein the row-wise computation comprises:
performing a first computation of self-attention algorithm to each of the plurality of target agents according to the first computation result and the second computation result to generate the first prediction result,
wherein the first computation of self-attention algorithm is configured to generate a plurality of predicted trajectories for the plurality of target agents, and perform a communication to the plurality of predicted trajectories to generate the first prediction result including a plurality of trajectories.

9. The method of claim 8, wherein the column-wise computation comprises:
performing a second computation of self-attention algorithm to the plurality of trajectories corresponding to the plurality of target agents according to the first computation result to generate the second prediction result,
wherein the second computation of self-attention algorithm is configured to perform a communication to the plurality of trajectories, and generate the second prediction result.

10. The method of claim 9, wherein
the first computation of self-attention algorithm is performed with an anchor-free mode algorithm, and generates the first prediction result according to a plurality of initialization vectors, and
the second computation of self-attention algorithm is performed with an anchor-based mode algorithm, and generates the second prediction result according to the first prediction result.

11. The method of claim 1, wherein the row-wise computation further comprises:
generating a query based on the first computation result;
generating a key and a value based on the second computation result; and
performing a computation of attention algorithm according to the query, the key, and the value.

12. A multi-agent trajectory prediction system, comprising:
a filter configured to filter a plurality of agents and generate a plurality of target agents;
an encoder configured to encode a plurality of agent data of the plurality of target agents to generate a scene data; and
a decoder configured to perform the following operations:
generating a first computation result and a second computation result according to the scene data;
performing a row-wise computation to the first computation result and the second computation result, and generating a first prediction result; and
performing a column-wise computation to the first prediction result, and generating a second prediction result,
wherein the second prediction result is configured to describe a plurality of trajectories of the plurality of target agents.

13. The multi-agent trajectory prediction system of claim 12, wherein
the decoder is configured to perform a computation of cross-attention algorithm to a time vector of the plurality of target agents correspondingly according to the scene data to generate the first computation result, and
wherein the decoder is configured to perform the computation of cross-attention algorithm to a scene vector of the plurality of target agents correspondingly according to the scene data to generate the second computation result.

14. The multi-agent trajectory prediction system of claim 12, wherein
the row-wise computation is configured to perform a first computation of self-attention algorithm to each of the plurality of target agents according to the first computation result and the second computation result to generate the first prediction result,
the row-wise computation is configured to perform a second computation of self-attention algorithm to a plurality of trajectories corresponding to the plurality of target agents according to the first computation result to generate the second prediction result, and
wherein the first computation of self-attention algorithm is configured to generate a plurality of predicted trajectories for the plurality of target agents, and perform a communication to the plurality of predicted trajectories, the second computation of self-attention algorithm is configured to perform a communication to the plurality of trajectories.

15. The multi-agent trajectory prediction system of claim 14, wherein
the first computation of self-attention algorithm is performed with an anchor-free mode parametric computation, and generates the first prediction result according to a plurality of initialization vectors, and
the second computation of self-attention algorithm is performed with an anchor-based mode parametric computation, and generates the second prediction result according to the first prediction result.

16. The multi-agent trajectory prediction system of claim 12, wherein
the filter is further configured to train a plurality of second agent data of the plurality of agents being different from the plurality of agent data during a time period in the past to generate a configurator, and
the configurator is configured to filter out the plurality of target agents according to a correlation of the plurality of agents.

17. The multi-agent trajectory prediction system of claim 16, wherein when the correlation is higher than a correlation threshold, filtering out corresponding agents of the plurality of agents as the plurality of target agents.

18. The multi-agent trajectory prediction system of claim 17, wherein
when physical distances between the plurality of agents and a vehicle are shorter, the correlation is higher, and
when the physical distances between the plurality of agents and the vehicle are longer, the correlation is lower.

19. The multi-agent trajectory prediction system of claim 12, wherein the row-wise computation further comprises:
generating a query based on the first computation result;
generating a key and a value based on the second computation result; and
performing a computation of attention algorithm according to the query, the key, and the value.

20. The multi-agent trajectory prediction system of claim 12, wherein the first computation result has a tensor being the same as a tensor of the second computation result.
